(19) United States
(12) Patent Application Publication
(10) Pub. No.: US 2012/0154257 A1
(43) Pub. Date: Jun. 21, 2012

(54) DISPLAY DEVICE AND METHOD OF CRYSTALLIZING THE SAME

(76) Inventors: Hyun-Been HWANG, Yongin-City (KR); Cheol-Ho Park, Yongin-City (KR); Kwon-Hyung Lee, Yongin-City (KR); Byoungkwon Choo, Yongin-City (KR); Minhwan Choi, Yongin-City (KR)

(21) Appl. No.: 13/301,977

(22) Filed: Nov. 22, 2011

(30) Foreign Application Priority Data
Dec. 15, 2010 (KR) 10-2010-0128421

(51) Int. Cl. G09G 3/20; H01L 33/08

(52) U.S. Cl. 345/55; 438/34

(57) ABSTRACT

A display device includes an active region including a plurality of unit pixels, the unit pixels including first circuit regions and image display regions, first peripheral regions adjacent to the active region, the first peripheral region including a plurality of second circuit regions, the first circuit regions and the second circuit regions being arranged along same virtual straight lines, and second peripheral regions adjacent to the active region, the second peripheral region including a plurality of third circuit regions.

### CROSS-REFERENCE TO RELATED APPLICATIONS

This U.S. non-provisional patent application claims priority under 35 U.S.C. §119 of Korean Patent Application No. 10-2010-0128421, filed on Dec. 15, 2010, the entire contents of which are hereby incorporated by reference.

### BACKGROUND

1. Field

The present disclosure herein relates to a display device and a method of crystallizing the same, and more particularly, to a display device having multi-crystal silicon and a method of crystallizing the same.

2. Description of the Related Art

Flat display devices may exhibit excellent characteristics, e.g., thin structure, light weight, and low consumption power. Examples of the flat display devices may include Liquid Crystal Displays (LCDs) and Organic Light Emitting Diode (OLED) displays.

A conventional flat display device may generally be an active matrix type including a switching device, e.g., a thin film transistor, that is turned on/off in each pixel for displaying a screen. Thin film transistors used in flat display devices having an active matrix type may include multi-crystal silicon, i.e., polysilicon. Since multi-crystal silicon has a greater field-effect mobility than that of amorphous silicon, response time of the flat display devices with polysilicon thin film transistors may be enhanced, and temperature and light stability may be improved. Multi-silicon is being used by depositing and crystallizing amorphous silicon.

### SUMMARY

The present disclosure provides a display device with enhanced productivity and a method of crystallizing the same.

Embodiments of the inventive concept provide a display device, including an active region including a plurality of unit pixels, the unit pixels including first circuit regions and image display regions, first peripheral regions adjacent to the active region, the first peripheral region including a plurality of second circuit regions, the first circuit regions and the second circuit regions being arranged along same virtual straight lines, and second peripheral regions adjacent to the active region, the second peripheral region including a plurality of third circuit regions.

The first circuit regions and the image display regions may be alternately arranged.

The virtual straight lines may extend in a row direction, the first circuit regions and the second circuit regions being aligned in the row direction.

The third circuit regions may extend in the row direction.

The virtual straight lines may include a plurality of lines separated from each by a constant interval along a column direction, the column direction being substantially perpendicular to the row direction.

The constant interval between the separated lines may correspond to a single image display region.

Two adjacent rows of first circuit regions may define one virtual straight line, each two adjacent rows of first circuit regions being separated from adjacent two rows of first circuit regions by two image display regions.

The first circuit regions and the second circuit regions may be arranged in a column direction.

The third circuit regions may extend in the column direction.

The virtual straight lines may be separated from each other at by a constant interval.

The virtual straight lines may be adjacent by one pair, and the adjacent pair of virtual straight lines are separated from each other by the same interval.

The first circuit region may include a circuit portion of the unit pixel, and the image display region may include an image display portion of the unit pixel.

In other embodiments of the inventive concept, a crystallization method of a display device includes forming an active region including a plurality of unit pixels on a substrate, the unit pixels including first circuit regions and image display regions, forming first peripheral regions adjacent to the active region on the substrate, the first peripheral region including a plurality of second circuit regions, the first circuit regions and the second circuit regions being arranged along same virtual straight lines, forming second peripheral regions adjacent to the active region on the substrate, the second peripheral region including a plurality of third circuit regions, and irradiating the first and second crystallization regions to simultaneously crystallize amorphous silicon into polycrystalline silicon in the first and second crystallization regions.

The crystallization method may further include crystallizing the third crystallization regions.

Irradiating the first and second crystallization regions may include scanning a laser along a direction substantially perpendicular to the virtual straight lines.

Scanning the laser may include scanning a one-time laser along a single direction.

The third crystallization regions may be formed to extend along a direction of the virtual straight lines.

Irradiating may include using a pulse laser or a continuous wave laser.

Irradiating includes using a laser via control of a turn-on/off time or a period.

The crystallization method may further include removing amorphous silicon to form non-crystallization regions, the non-crystallization regions being alternately arranged with respective first through third circuit regions.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a view of a display device and a method of crystallizing the same according to a first embodiment;

FIG. 2 is a view of a display device and a method of crystallizing the same according to a second embodiment;

FIG. 3 is a view of a display device and a method of crystallizing the same according to a third embodiment; and

FIG. 4 is a view of a display device and a method of crystallizing the same according to a fourth embodiment.

### DETAILED DESCRIPTION

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout.

Additionally, the embodiment in the detailed description will be described with respect to plan views as ideal exemplary views of the example embodiments. In the figures, the dimensions of layers and regions may be exaggerated for clarity of illustration. Accordingly, shapes of the exemplary views may be modified according to manufacturing techniques and/or allowable errors. Therefore, the embodiments are not limited to the specific shape illustrated in the exemplary views, but may include other shapes that may be created according to manufacturing processes. Also, though terms like a first, a second, and a third are used to describe various regions and layers in various embodiments, the regions and the layers are not limited to these terms. These terms are used only to discriminate one region or layer from another region or layer. An embodiment described and exemplified herein includes a complementary embodiment thereof.

In the following description, the technical terms are used only to explain a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

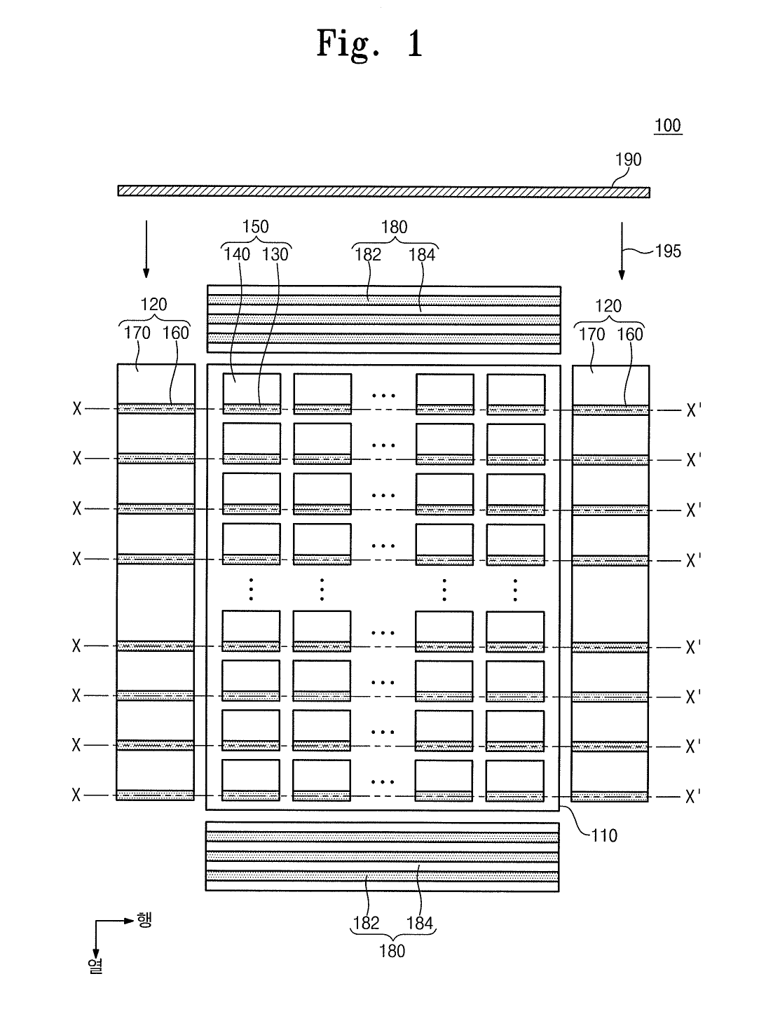

FIG. 1 is a view of a display device and a method of crystallizing the same according to a first embodiment. Referring to FIG. 1, a display device 100 includes an active region 110, and first and second peripheral regions 120 and 180 adjacent to the active region 110. The active region 110 includes a plurality of unit pixels 150. The unit pixels 150 may be arranged in an active matrix type. In other words, each of the unit pixels 150 may include a switching device, e.g., a thin film transistor.

The unit pixels 150, e.g., each unit pixel 150, may include a first crystallization region 130 and a first non-crystallization region 140. The first crystallization region 130 may include a first circuit portion of the unit pixel 150. For example, when the display device 100 is a LCD, the first circuit portion of the unit pixel 150 may include a thin film transistor. In another example, when the display device 100 is an OLED device, the first circuit portion of the unit pixel 150 may include a thin film transistor or a capacitor. The first crystallization region 130 may include polycrystalline silicon, i.e., polysilicon. The first non-crystallization region 140 may include an image display portion. The unit pixels 150 may be repeatedly arranged in a matrix pattern, e.g., the first crystallization regions 130 and first non-crystallization regions 140 may be alternately arranged along the y-axis in each column of unit pixels 150 in the matrix pattern.

The first peripheral region 120 includes second crystallization regions 160 and second non-crystallization regions 170. The second peripheral region 180 includes third crystallization regions 182 and third non-crystallization regions 184. The second crystallization regions 160 and the second non-crystallization regions 170 may be alternately arranged. For example, a single second crystallization region 160 may be between two second non-crystallization regions 170. Also, the third crystallization regions 182 and the third non-crystallization regions 184 may be alternately arranged.

The second crystallization regions 160 and the third crystallization regions 182 include polycrystalline silicon. The second crystallization regions 160 include a second circuit portion. The third crystallization regions 182 include a third circuit portion. The second circuit portion or the third circuit portion may include a thin film transistor or a diode, and the thin film transistor or the diode may include polycrystalline silicon. The thin film transistor or diode of the second crystallization regions 160 and third crystallization regions 182 may be an element of, e.g., a shift register, a demultiplexer, and/or a gate driver.

The first crystallization regions 130 and the second crystallization regions 160 may be arranged along the same virtual straight lines X-X′, i.e., the first crystallization regions 130 and the second crystallization regions 160 may be arranged along the virtual straight lines X-X′ in a row direction. In other words, the virtual straight lines X-X′ may be a plurality of lines X-X′ separated from each other along the y-axis, so the plurality of unit pixels 150 may be arranged to have their first crystallization regions 130 aligned with respective second crystallization regions 160 along respective X-X′ lines, i.e., along the x-axis. The third crystallization regions 182 may extend in the row direction, e.g., each third crystallization region 182 may extend along the x-axis.

A crystallization method of a display device according to a first embodiment is as follows.

Amorphous silicon is formed over the active region 110, the first peripheral region 120, and the second peripheral region 180. A laser 190 is irradiated on the first and second crystallization regions 130 and 160, so the amorphous silicon is crystallized into polycrystalline silicon. Uncrystallized amorphous silicon may be patterned and removed. The third crystallization regions 182 may be crystallized prior to the first and second crystallization regions 130 and 160. Alternatively, the third crystallization regions 182 may be crystallized after the first and second crystallization regions 130 and 160 are crystallized.

The laser 190 may include a pulse laser or a Continuous Wave (CW) laser. The laser 190 may use a beam having a long axis. A scanning direction 195, i.e., an irradiation direction of the laser 190, may be oriented in a column direction, i.e., a direction perpendicular to the virtual straight lines X-X′. The laser 190 may be scanned by controlling a turn-on/off time or a period. The first through third crystallization regions 130, 160, and 182 may be crystallized, and then amorphous silicon provided to the non-crystallization regions 140, 170, and 174 may be removed.

According to the first embodiment, the active region 110 and the first peripheral region 120 may be simultaneously crystallized. That is, as the first and second crystallization regions 130 and 160 are aligned, the first and second crystallization regions 130 and 160 may be simultaneously crystallized. Also, the third crystallization region 182 and the first and second crystallization regions 130 and 160 may be crystallized through one-time scanning. Therefore, crystallization may be completed through one-time laser scanning without changing the scanning direction of the laser 190 or rotating a laser stage. Accordingly, the process cost and process time of the display device 100 may be reduced.

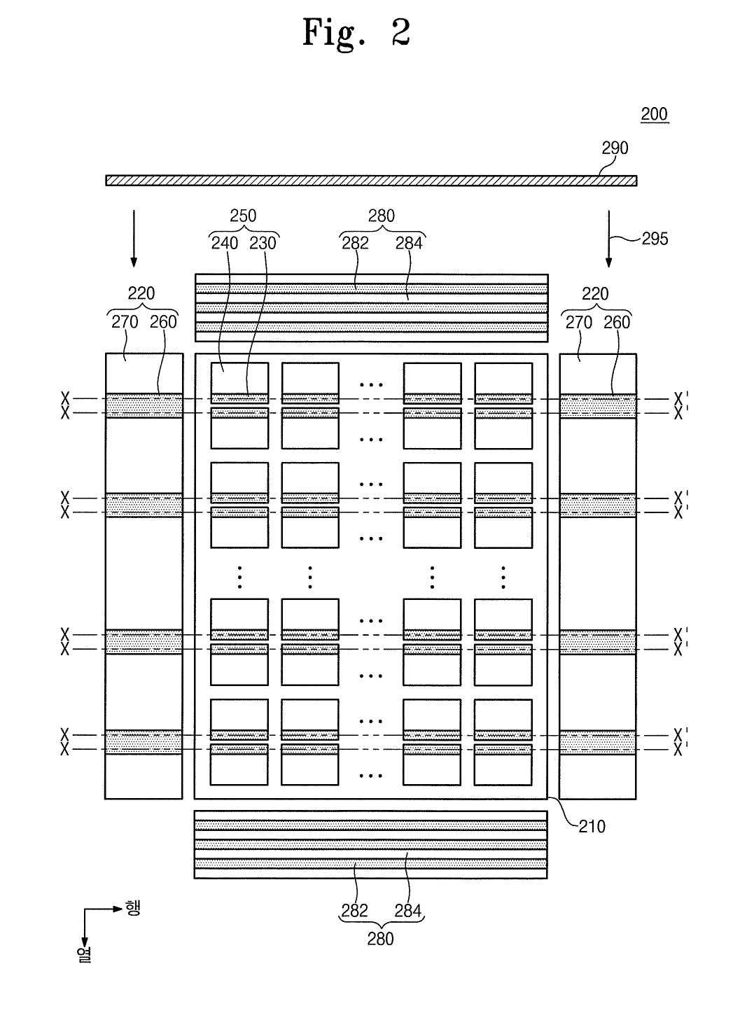

FIG. 2 is a view of a display device and a method of crystallizing the same according to a second embodiment. Detailed description of same technical features as those of the first embodiment described previously with reference to FIG. 1 will not be repeated.

Referring to FIG. 2, a display device 200 may include an active region 210, and first and second peripheral regions 220 and 280 adjacent to the active region 210. The active region 210 may include a plurality of unit pixels 250. The unit pixels 250 may be arranged in an active matrix type. The unit pixels 250, e.g., each unit pixel 250, may include a first crystallization region 230 and a first non-crystallization region 240. The first crystallization region 230 may include a first circuit portion of the unit pixels 250. The first crystallization region 230 may include polycrystalline silicon. The first non-crystallization region 240 may include an image display portion. The unit pixels 250 may be repeatedly arranged in a matrix pattern. That is, the first crystallization regions 230 of the unit pixels 250 may be arranged in pairs, so the first crystallization regions 230 of two adjacent unit pixels 250 may face each other and be adjacent to each other.

The first peripheral region 220 may include second crystallization regions 260 and second non-crystallization regions 270. The second peripheral region 280 may include third crystallization regions 282 and third non-crystallization regions 284. The second crystallization regions 260 and the second non-crystallization regions 270 may be alternately arranged. For example, as illustrated in FIG. 2, a pair of adjacent second crystallization regions 260 may have two second non-crystallization region 270 at each side. Also, the third crystallization regions 282 and the third non-crystallization regions 284 may be alternately arranged. The second crystallization regions 260 and the third crystallization regions 282 may include polycrystalline silicon.

The first crystallization regions 230 and the second crystallization regions 260 may be arranged along the same virtual straight lines X-X′, i.e., the first crystallization regions 230 and the second crystallization regions 260 may be arranged along the virtual straight lines X-X′ in a row direction. As each crystallized region in FIG. 2 refers to a pair of adjacent second crystallization regions 260, the virtual straight lines X-X′ may be adjacent by one pair, and the adjacent pair of virtual straight lines X-X′ may be separated from each other at the same distances. That is, the second crystallization regions 260 may be arranged in pairs corresponding to the pairs of the first crystallization regions 230, and may be arranged along the virtual straight lines X-X′. As such, the virtual lines X-X′ may be arranged in pairs corresponding to the pairs of first crystallization regions 230, and may be separated from each other along the y-axis to have a constant distance, e.g., corresponding to two non-crystallization regions 270. The third crystallization regions 282 may extend in the row direction.

A crystallization method of a display device according to the second embodiment is as follows.

Amorphous silicon is formed over the active region 210, the first peripheral region 220, and the second peripheral region 280. A laser 290 may be irradiated on the first and second crystallization regions 230 and 260, so the amorphous silicon is crystallized into polycrystalline silicon. Uncrystallized amorphous silicon may be patterned and removed. The third crystallization regions 282 may be crystallized prior to the first and second crystallization regions 230 and 260. Alternatively, the first and second crystallization regions 230 and 260 may be crystallized, and thereafter the third crystallization regions 282 may be crystallized.

The laser 290 may include a pulse laser or a Continuous Wave (CW) laser. A scanning direction 295, i.e., the irradiating direction of the laser 290, may be a column direction, i.e., a direction perpendicular to the virtual straight lines X-X′. The laser 290 may be scanned by controlling a turn-on/off time or a period.

According to the second embodiment, the active region 210 and the first peripheral region 220 may be simultaneously crystallized. That is, the first and second crystallization regions 230 and 260 may be simultaneously crystallized. Also, the third crystallization region 282 and the first and second crystallization regions 230 and 260 may be crystallized through one-time scanning. Therefore, crystallization may be completed through one-time laser scanning without changing the scanning direction of the laser 290 or rotating a laser stage. Accordingly, the process cost and process time of the display device 200 may be reduced.

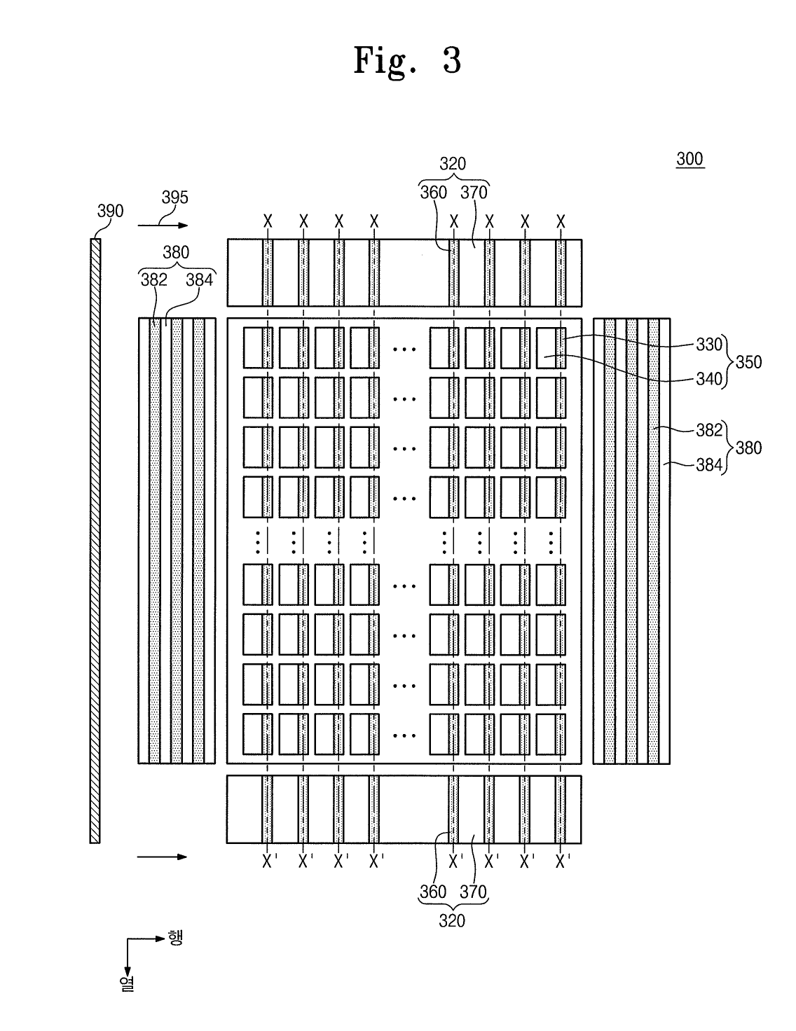

FIG. 3 is a view of a display device and a method of crystallizing the same according to a third embodiment. Detailed description of same technical features as those of the first embodiment described previously with reference to FIG. 1 will not be repeated.

Referring to FIG. 3, a display device 300 may include an active region 310, and first and second peripheral regions 320 and 380 adjacent to the active region 310. The active region 310 may include a plurality of unit pixels 350. The unit pixels 350 may be arranged in an active matrix type. The unit pixels 350 may include a first crystallization region 330 and a first non-crystallization region 340. The first crystallization region 330 may include a first circuit portion of the unit pixels 350. The first crystallization region 330 may include polycrystalline silicon. The first non-crystallization region 340 may include an image display portion. The unit pixels 350 may be repeatedly arranged in a matrix pattern.

The first peripheral region 320 may include second crystallization regions 360 and second non-crystallization regions 370. The second peripheral region 380 may includes third crystallization regions 382 and third non-crystallization regions 384. The second crystallization regions 360 and the second non-crystallization regions 370 may be alternately arranged. Also, the third crystallization regions 382 and the third non-crystallization regions 384 may be alternately arranged. The second crystallization regions 360 and the third crystallization regions 382 may include polycrystalline silicon.

The first crystallization regions 330 and the second crystallization regions 360 may be arranged along the same virtual straight lines X-X′. In other words, the first crystallization regions 330 and the second crystallization regions 360 may be arranged along the virtual straight lines X-X′ in a column direction. The virtual straight lines X-X′ may be separated from each other at the same distances. The third crystallization regions 382 may be extended in the column direction.

A crystallization method of a display device according to the third embodiment of the inventive concept is as follows.

Amorphous silicon is formed over the active region 310, the first peripheral region 320, and the second peripheral region 380. A laser 390 is irradiated on the first and second crystallization regions 330 and 360, so the amorphous silicon is crystallized into polycrystalline silicon. Uncrystallized amorphous silicon may be patterned and removed. The third crystallization regions 382 may be crystallized prior to the first and second crystallization regions 330 and 360. Alternatively, the first and second crystallization regions 330 and 360 may be crystallized, and thereafter the third crystallization regions 382 may be crystallized.

The laser 390 may include a pulse laser or a Continuous Wave (CW) laser. A scanning direction 395 which is the irradiating direction of the laser 390 may be a row direction, i.e., a direction perpendicular to the virtual straight lines X-X′. The laser 390 may be scanned by controlling a turn-on/off time or a period.

According to the third embodiment, the active region 310 and the first peripheral region 320 may be simultaneously crystallized. That is, the first and second crystallization regions 330 and 360 may be simultaneously crystallized. Also, the third crystallization region 382 and the first and second crystallization regions 330 and 360 may be crystallized through one-time scanning. Therefore, crystallization may be completed through one-time laser scanning without changing the scanning direction of the laser 390 or rotating a laser stage. Accordingly, the process cost and process time of the display device 300 can be reduced.

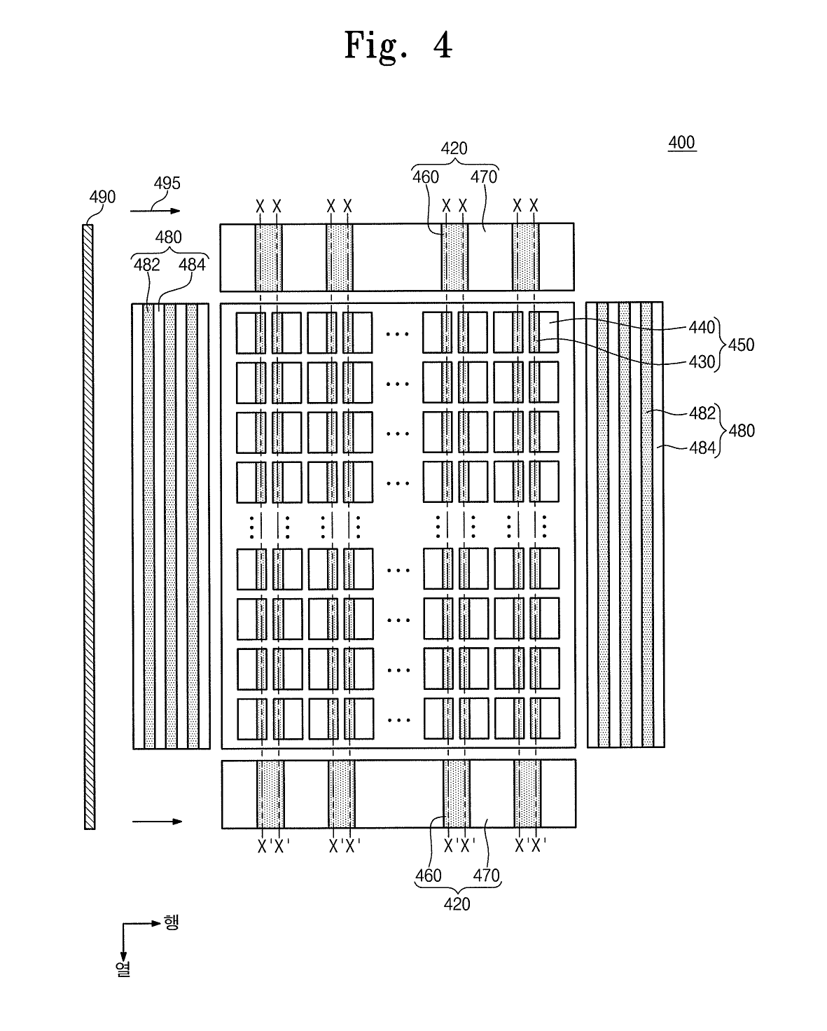

FIG. 4 is a view of a display device and a method of crystallizing the same according to a fourth embodiment. Detailed description of same technical features as those of the first embodiment described previously with reference to FIG. 1 will not be repeated.

Referring to FIG. 4, a display device 400 may include an active region 410, and first and second peripheral regions 420 and 480 adjacent to the active region 410. The active region 410 may include a plurality of unit pixels 450. The unit pixels 450 may be arranged in an active matrix type. The unit pixels 450 may include a first crystallization region 430 and a first non-crystallization region 440. The first crystallization region 430 may include a first circuit portion of the unit pixels 450. The first crystallization region 430 may include polycrystalline silicon. The first non-crystallization region 440 may include an image display portion. The unit pixels 450 may be repeatedly arranged in a matrix pattern.

The first peripheral region 420 may include second crystallization regions 460 and second non-crystallization regions 470. The second peripheral region 480 may include third crystallization regions 482 and third non-crystallization regions 484. The second crystallization regions 460 and the second non-crystallization regions 470 may be alternately arranged. Also, the third crystallization regions 482 and the third non-crystallization regions 484 may be alternately arranged. The second crystallization regions 460 and the third crystallization regions 482 may include polycrystalline silicon.

The first crystallization regions 430 and the second crystallization regions 460 may be arranged along the same virtual straight lines X-X′. In other words, the first crystallization regions 430 and the second crystallization regions 460 may be arranged along the virtual straight lines X-X′ in a column direction. The virtual straight lines X-X′ are adjacent by one pair, and the adjacent pair of virtual straight lines X-X′ may be separated from each other at the same distances. That is, the first crystallization regions 430 arranged along the virtual straight lines X-X′ may be adjacently arranged by one pair. The third crystallization regions 482 may be extended in the column direction.

A crystallization method of a display device according to the fourth embodiment is as follows.

Amorphous silicon is formed over the active region 410, the first peripheral region 420, and the second peripheral region 480. A laser 490 is irradiated on the first and second crystallization regions 430 and 460, so the amorphous silicon is crystallized into polycrystalline silicon. Uncrystallized amorphous silicon may be patterned and removed. The third crystallization regions 482 may be crystallized prior to the first and second crystallization regions 430 and 460. Alternatively, the first and second crystallization regions 430 and 460 may be crystallized, and thereafter the third crystallization regions 482 may be crystallized.

The laser 490 may include a pulse laser or a Continuous Wave (CW) laser. A scanning direction 495, i.e., an irradiating direction of the laser 490, may be a row direction, i.e., a direction perpendicular to the virtual straight lines X-X′. The laser 490 may be scanned by controlling a turn-on/off time or a period.

According to the fourth embodiment of the inventive concept, the active region 410 and the first peripheral region 420 may be simultaneously crystallized. That is, the first and second crystallization regions 430 and 460 may be simultaneously crystallized. Also, the third crystallization region 482 and the first and second crystallization regions 430 and 460 may be crystallized through one-time scanning. Therefore, crystallization may be completed through one-time laser scanning without changing the scanning direction of the laser 490 or rotating a laser stage. Accordingly, the process cost and process time of the display device 400 may be reduced.

According to embodiments, the active region and the peripheral region may be simultaneously crystallized. That is, the crystallization region of the active region and the crystallization region of the peripheral region may be aligned and simultaneously crystallized. Further, the crystallization region of the active region and the crystallization region of the peripheral region may be crystallized through one-time scanning. Therefore, crystallization may be completed through one-time laser scanning without changing the scanning direction of the laser or rotating the laser stage. Accordingly, the process cost and process time of the display device may be reduced.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A display device, comprising:
an active region including a plurality of unit pixels, the unit pixels including first circuit regions and image display regions;
first peripheral regions adjacent to the active region, the first peripheral region including a plurality of second circuit regions, the first circuit regions and the second circuit regions being arranged along same virtual straight lines; and
second peripheral regions adjacent to the active region, the second peripheral region including a plurality of third circuit regions.

2. The display device of claim 1, wherein the first circuit regions and the image display regions are alternately arranged.

3. The display device of claim 2, wherein the virtual straight lines extend in a row direction, the first circuit regions and the second circuit regions being aligned in the row direction.

4. The display device of claim 3, wherein the third circuit regions extend in the row direction.

5. The display device of claim 3, wherein the virtual straight lines include a plurality of lines separated from each by a constant interval along a column direction, the column direction being substantially perpendicular to the row direction.

6. The display device of claim 5, wherein the constant interval between the separated lines corresponds to a single image display region.

7. The display device of claim 5, wherein two adjacent rows of first circuit regions define one virtual straight line, each two adjacent rows of first circuit regions being separated from adjacent two rows of first circuit regions by two image display regions.

8. The display device of claim 2, wherein the first circuit regions and the second circuit regions are arranged in a column direction.

9. The display device of claim 8, wherein the third circuit regions extend in the column direction.

10. The display device of claim 8, wherein the virtual straight lines are separated from each other at by a constant interval.

11. The display device of claim 10, wherein the virtual straight lines are adjacent by one pair, and the adjacent pair of virtual straight lines are separated from each other by the same interval.

12. The display device of claim 1, wherein:
the first circuit region includes a circuit portion of the unit pixel, and
the image display region includes an image display portion of the unit pixel.

13. A crystallization method of a display device, the crystallization method comprising:
forming an active region including a plurality of unit pixels on a substrate, the unit pixels including first circuit regions and image display regions;
forming first peripheral regions adjacent to the active region on the substrate, the first peripheral region including a plurality of second circuit regions, the first circuit regions and the second circuit regions being arranged along same virtual straight lines;
forming second peripheral regions adjacent to the active region on the substrate, the second peripheral region including a plurality of third circuit regions; and
irradiating the first and second crystallization regions to simultaneously crystallize amorphous silicon into polycrystalline silicon in the first and second crystallization regions.

14. The crystallization method of claim 13, further comprising crystallizing the third crystallization regions.

15. The crystallization method of claim 14, wherein irradiating the first and second crystallization regions includes scanning a laser along a direction substantially perpendicular to the virtual straight lines.

16. The crystallization method of claim 15, wherein scanning the laser includes scanning a one-time laser along a single direction.

17. The crystallization method of claim 14, wherein the third crystallization regions are formed to extend along a direction of the virtual straight lines.

18. The crystallization method of claim 13, wherein irradiating includes using a pulse laser or a continuous wave laser.

19. The crystallization method of claim 13, wherein irradiating includes using a laser via control of a turn-on/off time or a period.

20. The crystallization method of claim 13, further comprising removing amorphous silicon to form non-crystallization regions, the non-crystallization regions being alternately arranged with respective first through third circuit regions.
